(19) United States
(12) Patent Application Publication
(10) Pub. No.: US 2014/0103481 A1
(43) Pub. Date: Apr. 17, 2014

(54) SEMICONDUCTOR SUBSTRATE, SEMICONDUCTOR DEVICE, SOLID-STATE IMAGING DEVICE, AND METHOD OF MANUFACTURING SEMICONDUCTOR SUSTRATE

(71) Applicant: OLYMPUS CORPORATION, Tokyo (JP)

(72) Inventors: Shugo Ishizuka, Tokyo (JP); Yuichi Gomi, Tokyo (JP); Yoshiaki Takemoto, Tokyo (JP)

(73) Assignee: OLYMPUS CORPORATION, Tokyo (JP)

(21) Appl. No.: 14/046,394

(22) Filed: Oct. 4, 2013

(30) Foreign Application Priority Data
Oct. 17, 2012 (JP) 2012-229760

(51) Int. Cl. H01L 31/02; H01L 31/18

(52) U.S. Cl. CPC H01L 31/02002; H01L 31/18
USPC 257/466; 438/667

(57) ABSTRACT

A semiconductor substrate according to the present invention includes: a substrate; an electrode array which is provided on the surface on one side in a thickness direction of the substrate and in which a plurality of electrodes is two-dimensionally arranged in a plan view; and a resin layer which is provided on the surface on one side and seals peripheries of the plurality of electrodes. The plurality of electrodes protrudes by greater than or equal to 5% of its own height on the resin layer and is capable of being accommodated in the resin layer by being compressed in the thickness direction.

### BACKGROUND OF THE INVENTION

1. Field of the Invention

The present invention relates to a semiconductor substrate, more specifically, a semiconductor substrate in which a large number of electrodes are formed on a substrate, a semiconductor device and a solid-state imaging device using the semiconductor substrate, and a method of manufacturing a semiconductor substrate.

Priority is claimed on Japanese Patent Application No. 2012-229760, filed Oct. 17, 2012, the contents of which are incorporated herein by reference.

2. Description of Related Art

For higher performance and a reduction in the size of a system, a smaller and higher-performance semiconductor device is required, and a stacked semiconductor device which is configured by joining wafers with a large number of minute electrodes formed thereon to each other has been studied.

In the stacked semiconductor device, semiconductor substrates are connected by electrodes. However, connection by only electrodes is weak with respect to an external force or stress, and corrosion of the electrode sometimes occurs due to humidity, temperature, or the like. In order to prevent this, there is a case where portions other than the electrodes between the semiconductor substrates are sealed by a resin called an underfill. The sealing by the underfill is usually performed by injecting the underfill from the gap between the semiconductor substrates after connection of the electrodes. However, due to a reduction in pitch of the electrodes in recent years and a reduction in a gap according to the reduction in pitch, it has become difficult to inject the underfill after the connection.

Therefore, in recent years, attention has been paid to a method in which connection is performed after the underfill is applied onto the semiconductor substrate before connection of the electrodes. As a method of obtaining a connection structure in which the electrode and the underfill can be connected at the same time, for example, Japanese Unexamined Patent Application, First Publication No. 2005-64451 can be given. In Japanese Unexamined Patent Application, First Publication No. 2005-64451, a method is disclosed in which the underfill is applied onto the entire surface after electrodes are formed on a substrate and in order to simultaneously realize exposure of the electrodes from the underfill and planarization, the surface of the underfill is cut.

In addition, a method is also proposed in which after an electrode pattern is formed by using a photosensitive underfill and an electrode material such as copper is embedded therein, planarization is performed by chemical mechanical polishing (CMP).

### SUMMARY OF THE INVENTION

According to a first aspect of the present invention, a semiconductor substrate is provided including: a substrate; an electrode array which is provided on a surface on one side in a thickness direction of the substrate and in which a plurality of electrodes is two-dimensionally arranged in a plan view; and a resin layer which is provided on the surface on one side and seals peripheries of the plurality of electrodes, in which the plurality of electrodes protrudes further than the height in the thickness direction of the resin layer by greater than or equal to 5% of a height that is a dimension in the thickness direction of the electrode and is capable of being accommodated in the resin layer by being compressed in the thickness direction.

According to a second aspect of the present invention, in the first aspect, the plurality of electrodes may be formed by using metal so as to have a porous structure.

According to a third aspect of the present invention, in the first aspect, the plurality of electrodes may be formed of a resin material having electrical conductivity.

A semiconductor device according to a fourth aspect of the present invention may include the semiconductor substrate according to any one of the first aspect to the third aspect.

A solid-state imaging device according to a fifth aspect of the present invention may include the semiconductor device according to the fourth aspect.

According to a sixth aspect of the present invention, a method of manufacturing a semiconductor substrate is provided including: forming a resin layer on a surface on one side of a substrate; forming a sacrificial layer on the resin layer; forming an opening portion which penetrates the sacrificial layer and the resin layer and in which the substrate is exposed at a bottom portion; filling an electrode material in the opening portion; and removing the sacrificial layer, thereby forming an electrode which protrudes in a thickness direction of the substrate further than the resin layer.

According to a seventh aspect of the present invention, in the sixth aspect, in the thickness direction, a thickness of the sacrificial layer may be greater than or equal to 5% of the sum of a thickness of the resin layer and the thickness of the sacrificial layer.

### BRIEF DESCRIPTION OF THE DRAWINGS

FIG. 1 shows a plan view showing a semiconductor substrate according to an embodiment of the present invention, on the upper side of the paper, and a diagram showing an operation of joining the semiconductor substrate, on the lower side of the paper.

FIG. 2 is an enlarged view showing a unit area of the semiconductor substrate.

FIG. 3 is a cross-sectional view of an electrode array in the semiconductor substrate.

FIG. 4A is a diagram showing one process of the manufacturing of the semiconductor substrate.

FIG. 4B is a diagram showing one process of the manufacturing of the semiconductor substrate.

FIG. 4C is a diagram showing one process of the manufacturing of the semiconductor substrate.

FIG. 4D is a diagram showing one process of the manufacturing of the semiconductor substrate.

FIG. 4E is a diagram showing one process of the manufacturing of the semiconductor substrate.

FIG. 4F is a diagram showing one process of the manufacturing of the semiconductor substrate.

FIG. 5A is a diagram showing one process of the joining of the semiconductor substrate.

FIG. 5B is a diagram showing one process of the joining of the semiconductor substrate.

FIG. 5C is a diagram showing one process of the joining of the semiconductor substrate.

FIG. 5D is a diagram showing one process of the joining of the semiconductor substrate.

FIG. 6A is a diagram showing one process of obtaining individual pieces.

FIG. 6B is a perspective view showing one unit area cut as a semiconductor device.

### DETAILED DESCRIPTION OF THE INVENTION

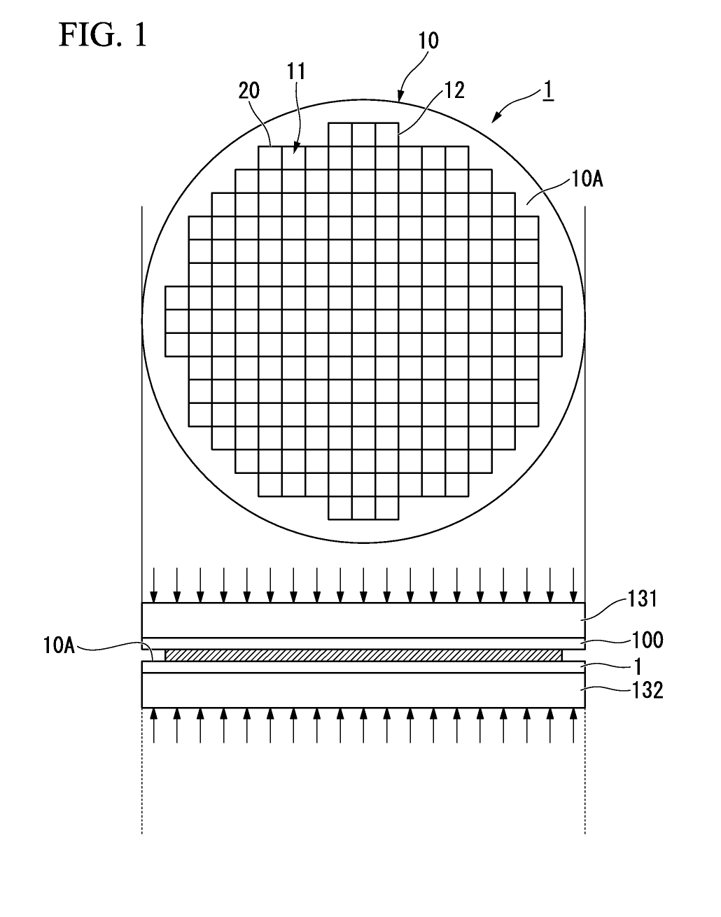

An embodiment of the present invention will be described referring to FIGS. 1 to 6B.

The upper side of the paper of FIG. 1 is a plan view showing a semiconductor substrate 1 of this embodiment. The semiconductor substrate 1 includes a substrate 10 having a plate shape or a sheet shape and a plurality of electrode arrays 20 formed on the surface of the substrate 10.

The substrate 10 is formed in a plate shape or a sheet shape having a predetermined thickness of an insulator or a semiconductor. As the insulator and the semiconductor constituting the substrate 10, for example, silicon, resin, ceramic, glass, or the like can be used. In this embodiment, as the substrate 10, a silicon wafer is used.

Further, although illustration is omitted, a wiring electrically connected to the electrode array 20 is formed on the substrate 10. An aspect of the wiring may be formed on the surface on one side or the surfaces on both sides in a thickness direction of the substrate 10 by printing, etching, or the like and may also be formed so as to penetrate the substrate like a via or the like. Moreover, three-dimensional wiring using a laminating technique is also acceptable and these may also be combined appropriately. Further, a semiconductor element may be mounted on the substrate 10.

The surface on one side of the substrate 10 becomes a joint surface 10A which is joined to another semiconductor substrate. A plurality of rectangular unit areas 11 is provided on the joint surface 10A, and the electrode array 20 in which a plurality of electrodes is formed in the same layout is formed one for each unit area 11 and the wiring of the same aspect is formed at each unit area 11.

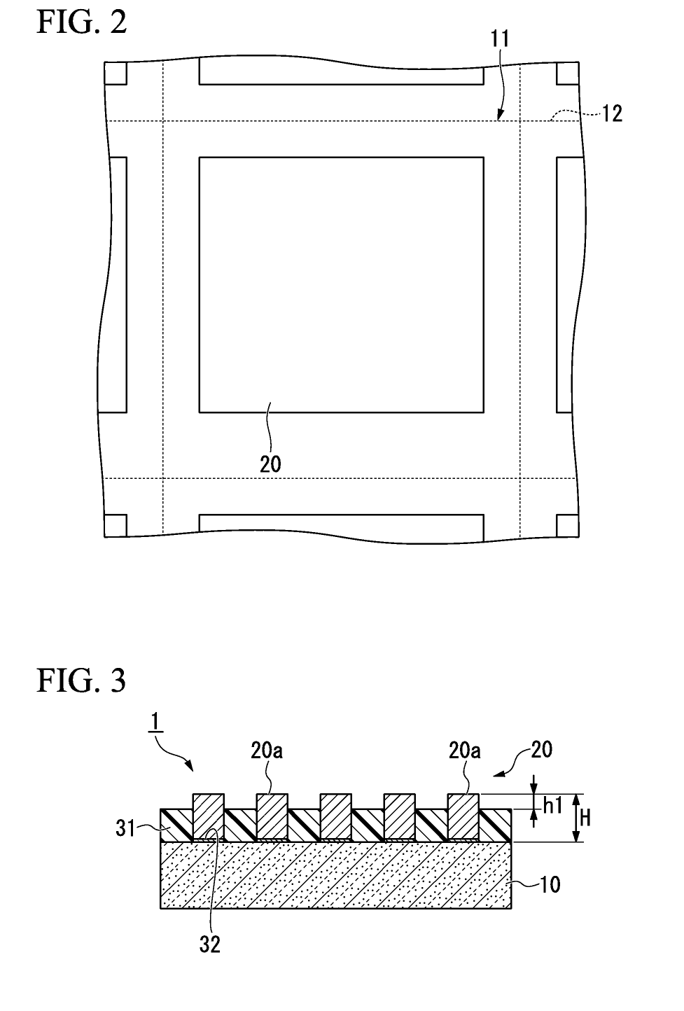

FIG. 2 is a schematic diagram showing the enlarged unit area 11. The electrode array 20 is formed in a substantially rectangular shape in the plan view of the substrate 1 by two-dimensionally arranging a large number of minute electrodes which protrude on the substrate 10. A boundary line 12 between adjacent unit areas becomes a cutting-off line, a so-called scribe line, when obtaining individual pieces which will be described later. However, since it is a conceptional line, the boundary line 12 need not be necessarily formed linearly on the substrate 10.

FIG. 3 is a partially enlarged view showing the cross section of the electrode array 20 of the unit area 11. A resin layer 31 which has insulation properties, seals the peripheries of individual electrodes 20a constituting the electrode array 20, and protects each electrode 20a is formed on the substrate 10. Each electrode 20a is formed so as to protrude from the upper surface of the resin layer 31 and connected to an electrode pad 32 which penetrates the resin layer 31 and is formed on the substrate 10. The electrode pad 32 is electrically connected to the wiring formed on the substrate 10 and the electrode array 20 is electrically connected to the wiring through the electrode pad 32.

As a material of the resin layer 31, for example, any of epoxy, benzocyclobutene, polyimide, and polybenzoxazole, a composite material of those, or the like can be given. All these materials have a characteristic in which adhesion is possible by heating and pressurization.

The electrode pad 32 is formed in a multi-layer structure or the like using, for example, any of Au, Cu, Al, Ni, Ti, Cr, and W, an alloy of those, or two or more of the metals, and there is no particular limitation to a forming method or a structure thereof. The electrode pad 32 may be formed by widening of the width of a portion of the wiring, or the like. Further, the electrode 20a and the wiring formed on the substrate 10 may be directly connected to each other without providing the electrode pad.

As shown in FIG. 3, a protrusion length h1 of each electrode 20a from the resin layer 31 is greater than or equal to at least 5% of a height H of the electrode 20a. Each electrode 20a is configured so as to be compressed in a height direction by a relatively small force and is compressed, thereby being able to be deformed until it has the same height as the resin layer 31 and is accommodated in the resin layer 31. The upper limit of the protrusion length h1 can be appropriately set in a range satisfying this condition. For example, in a case where the height H is in a range of 10 μm to 30 μm, the upper limit of the protrusion length h1 can be set to be greater than or equal to 5% of the height H and less than or equal to 50% of the height H. Further, if the electrode 20a can be deformed until it is accommodated in the resin layer 31 by compression, the protrusion length h1 of each electrode 20a need not be uniform and even if there is variation, this does not matter at all.

In the electrode 20a having a dense structure formed of metal, even if a normal compressive force acts thereon, a dimension in a compression direction cannot be reduced by greater than or equal to 5%. In the embodiment of the present invention, in order to enable the deformation as described above by compression, the electrode 20a is formed by using a metal material so as to take a porous structure having minute voids in the inside. As a method of forming an electrode having the porous structure, for example, a plating method such as electrolytic plating or electroless plating, a squeegee printing method using paste of metal particles, or the like can be given. Among them, since the electroless plating has the advantage that electrodes having uniform heights can be formed in a plane, it is suitable.

An example of the manufacturing procedure of the semiconductor substrate 1 configured as described above will be described.

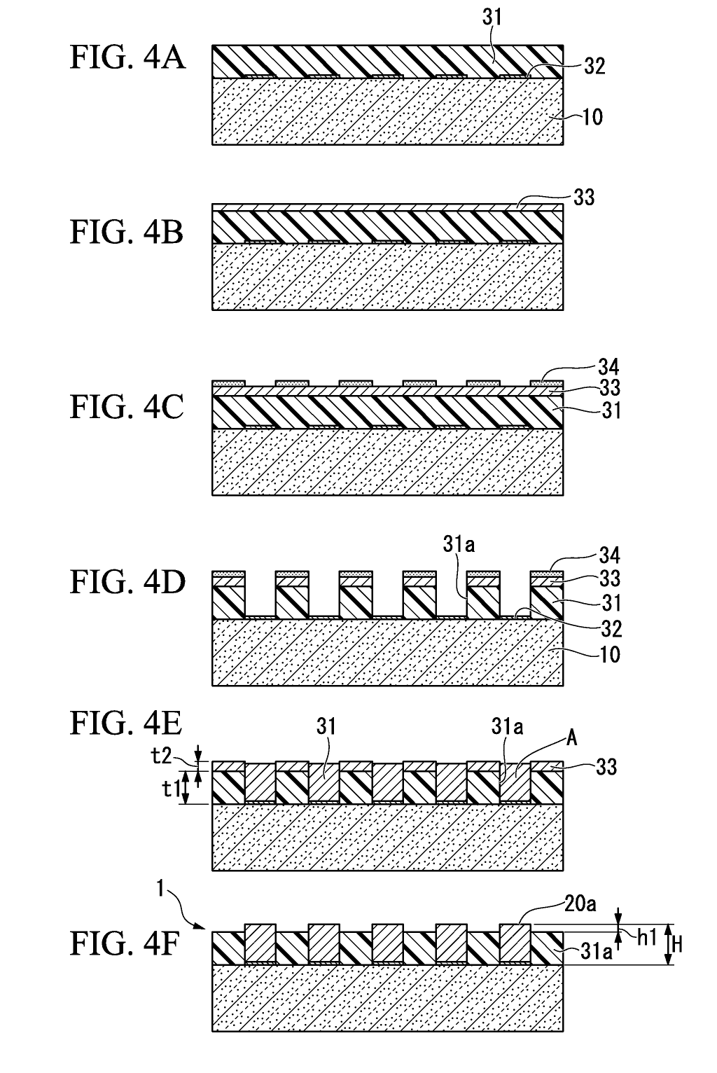

First, as shown in FIG. 4A, the resin layer 31 is formed on the surface of the substrate 10 with the electrode pad 32 and wiring (not shown) formed thereon. There is no particular limitation to a method of forming the resin layer 31, and the method of forming the resin layer 31 can be appropriately selected from various known methods such as a spin coating method, a squeegee printing method, and a vacuum lamination method in consideration of a material or the like.

Next, as shown in FIG. 4B, a sacrificial layer 33 is formed on the resin layer 31. The sacrificial layer 33 is a layer for forming the portion protruding on the resin layer 31 of the electrode 20a. Therefore, it is preferable that the thickness thereof be formed in a range of the protrusion length in which the above-described deformation is possible. As a material of the sacrificial layer 33, SiO₂, SiN, or the like can be given. As a method of forming the sacrificial layer 33, a sputtering method, an evaporation method, a CVD method, or the like can be given and there is no particular limitation.

Next, as shown in FIG. 4C, a resist pattern 34 is formed on the sacrificial layer 33, and then, as shown in FIG. 4D, the sacrificial layer 33 and the resin layer 31 are etched with the resist pattern 34 as a mask. In this way, opening portions 31a penetrating the sacrificial layer 33 and the resin layer 31 are formed in the resin layer 31 according to the resist pattern 34. The electrode pad 32 that is a portion of the substrate 10 is exposed at a bottom portion of the opening portion 31a.

In addition, the opening portion 31a may be formed by using a photosensitive material in the resin layer 31 and using photolithography, in addition to a wet etching method or a plasma etching method.

Next, as shown in FIG. 4E, a material (an electrode material) A of the electrode 20a is filled in the opening portions 31a so as to fill the opening portions 31a to the height of the sacrificial layer 33.

Finally, if the sacrificial layer 33 is removed, as shown in FIG. 4F, the electrode 20a protruding on the resin layer 31 by a length generally corresponding to the thickness of the sacrificial layer 33 is formed, and thus the semiconductor substrate 1 is completed. Therefore, as shown in FIGS. 4E and 4F, when the thickness of the resin layer 31 is t1 and the thickness of the sacrificial layer 33 is t2, in a case where it is desired to set the protrusion length h1 of the electrode to be formed to be n % of the height H, it is desirable to set t1 and t2 so as to satisfy the expression, t2=(t1+t2)×n(%).

The removal of the sacrificial layer 33 can be performed by a wet etching method, a plasma etching method, or the like. However, at this time, it is preferable to set conditions or the like so as not to cause a large amount of damage to the resin layer 31 or the electrode 20a, and then perform the removal.

The semiconductor substrate 1 and a substrate 100 that faces the semiconductor substrate 1 are sandwiched between pressurizing plates 131 and 132 in a state where the joint surface 10A faces the substrate 100, as shown on the lower side of the paper of FIG. 1, and then joined together by pressurization and heating joining using a press apparatus (not shown). In this way, the semiconductor substrate 1 and the substrate 100 are joined while being electrically connected, and thus a semiconductor device is configured. Further, a configuration is also acceptable in which the surfaces and electrode sections of both the substrates are cleaned by plasma cleaning, reverse sputtering, or the like before joining and the electrodes are then joined to each other by using so-called surface activation. At this time, it is preferable to perform the joining in a vacuum atmosphere, a nitrogen atmosphere, or the like in consideration of the influence or the like of oxidation on the electrode array 20 and the resin layer 31.

In addition, there is no particular limitation to the substrate that faces the semiconductor substrate 1, and for example, another semiconductor substrate 1 is also acceptable and a substrate in which only an electrode pad and wiring are formed on a joint surface is also acceptable.

Hereinafter, an operation of the semiconductor substrate 1 at the time of joining will be described taking as an example a case where the substrate 100 faces the semiconductor substrate 1 and only an electrode pad and wiring is formed on the substrate 100.

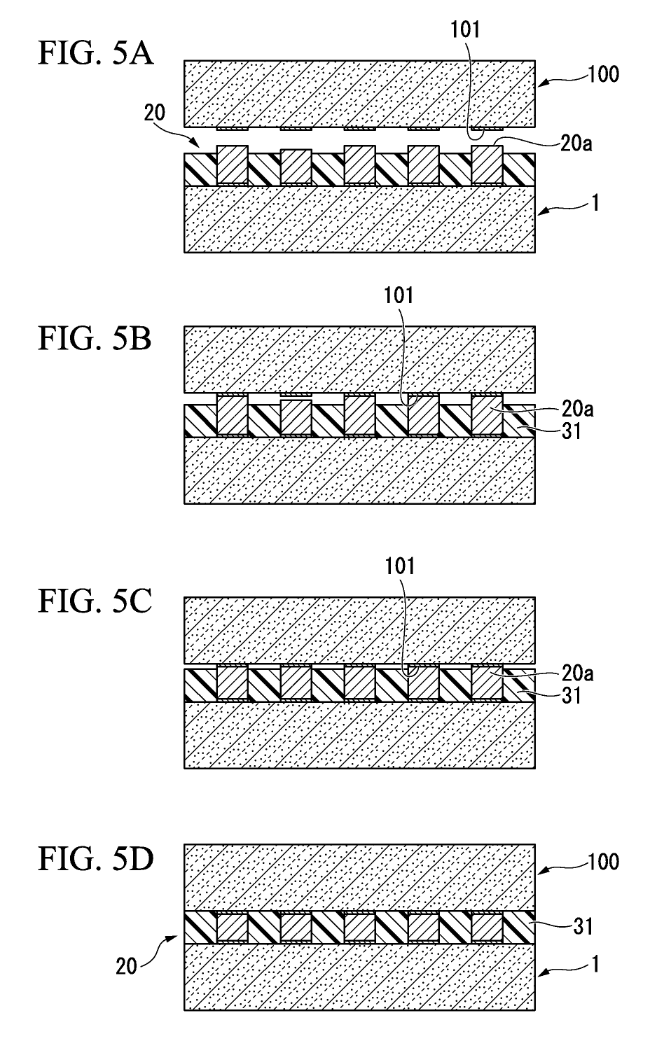

First, alignment of the semiconductor substrate 1 and the substrate 100 is performed such that the electrode 20a and an electrode pad 101 are aligned. For the alignment, a known wafer joining device or the like can be used. If the semiconductor substrate 1 and the substrate 100 are brought close to each other in an aligned state, as shown in FIG. 5A, the electrode array 20 eventually comes into contact with the electrode pad 101 on the substrate 100. As shown in FIG. 5B, at the stage when the electrode array 20 and the electrode pad 101 have begun to come into contact with each other, since there is variation in the protrusion lengths of the individual electrodes 20a, there are the electrode 20a which is in contact with the electrode pad 101 and an electrode 20b which is not in contact with the electrode pad 101.

Subsequently, if pressure is applied to the semiconductor substrate 1 and the substrate 100 while performing heating, the electrode 20a which is in contact with the electrode pad 101 is compressed first, whereby the protrusion length is shortened. If pressure is further applied, as shown in FIG. 5C, all the electrodes 20a reliably come into contact with the electrode pads 101.

If heating and pressurization are further continued, each electrode 20a is further compressed, thereby being accommodated in the resin layer 31. As shown in FIG. 5D, if the substrate 100 comes into contact with the resin layer 31, compression of the electrode array 20 is stopped. If heating and pressurization are further performed in this state, whereby the resin layer 31 and the substrate 100 are bonded to each other, joining of the semiconductor substrate 1 and the substrate 100 is finished.

Here, a case where two substrates are joined to each other has been taken and described as an example. However, more substrates may be joined to each other. In this case, for example, the resin layer 31 and the electrode array 20 may be formed on both surfaces of a single semiconductor substrate 1.

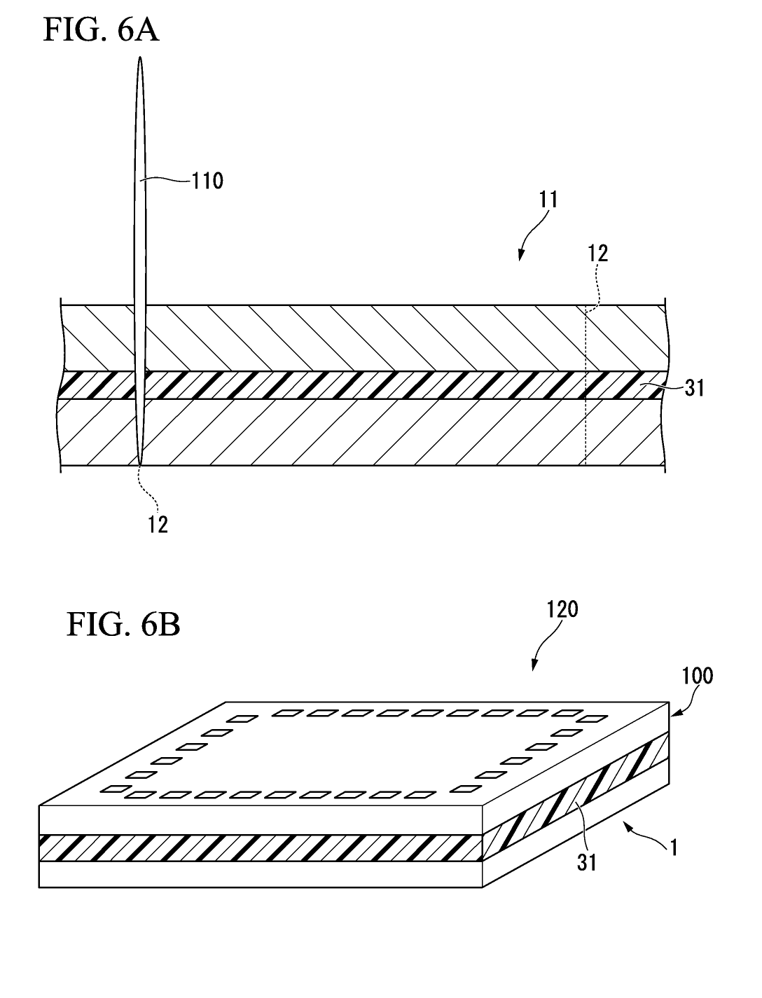

After the joining of the substrates, if the joined substrates are cut for each unit area 11 along the boundary line 12 by a blade 110 or the like (are divided into individual pieces), as shown in FIG. 6A, a semiconductor device 120 is completed in which the gap between the semiconductor substrate 1 and the substrate 100 is sealed by the resin layer 31, as shown in FIG. 6B.

As described above, according to the semiconductor substrate 1 of this embodiment, since a plurality of electrodes 20a in the electrode array 20 protrudes greater than or equal to 5% of its own height on the resin layer 31 and can be accommodated in the resin layer 31 by being compressed in the height direction, even if the protrusion length of each electrode varies, all the electrodes can be reliably connected to a substrate that faces the semiconductor substrate 1 by heating and pressurization at the time of joining.

Further, since the electrode 20a can be greatly compressed in the height direction, an allowable range of variation in protrusion length in an electrode forming process is wide. As a result, a planarization process such as cutting or CMP is almost not required after electrode formation, and thus manufacturing efficiency can be significantly improved and yield can also be improved.

In addition, according to the method of manufacturing a semiconductor substrate in this embodiment, by appropriately setting the thickness of the sacrificial layer 33, it is possible to roughly control the protrusion length of the electrode 20a. Therefore, in the present invention, coupled with the fact that an allowable range of variation in protrusion length in electrode formation is wide, as described above, it is possible to completely omit a planarization process.

While preferred embodiments of the present invention have been described and illustrated above, it should be understood that these are exemplary of the present invention and are not to be considered as limiting. Additions, omissions, substitutions, and other modifications can be made without departing from the spirit or scope of the present invention. Accordingly, the present invention is not to be considered as being limited by the foregoing description, and is only limited by the scope of the appended claims.

For example, first, in the present invention, the shape in the plan view of the electrode array is not limited to a rectangular shape and there is no particular limitation. Further, the number or a disposition aspect of electrodes in the unit area may also be appropriately set in consideration of the configuration or the like of a semiconductor device to be manufactured.

Further, the electrode in the present invention is not limited to an electrode having the above-described porous structure made of metal. For example, even if the electrode is formed of a resin material having electrical conductivity, such as conductive resin or a resin material with conductive fillers mixed therein, since the electrode can be greatly compressed in the height direction, the same effects can be obtained.

In addition, the types of the semiconductor substrate according to the present invention and a semiconductor device using the semiconductor substrate are not particularly limited. However, for example, in a solid-state imaging device or the like having a large number of pixels, since it is necessary for a very large number of circuit electrodes to be formed at a narrow pitch, for example, in order for the diameter of the circuit electrode or a formation pitch of the circuit electrode to be 20 μm, a merit which is obtained by applying the present invention is very large and it is very suitable to apply the structure according to the present invention.

What is claimed is:

1. A semiconductor substrate comprising:
a substrate;
an electrode array which is provided on a surface on one side in a thickness direction of the substrate and in which a plurality of electrodes is two-dimensionally arranged in a plan view; and
a resin layer which is provided on the surface on one side and seals peripheries of the plurality of electrodes,
wherein the plurality of electrodes protrudes further than the height in the thickness direction of the resin layer by greater than or equal to 5% of a height that is a dimension in the thickness direction of the electrode and is capable of being accommodated in the resin layer by being compressed in the thickness direction.

2. The semiconductor substrate according to claim 1, wherein the plurality of electrodes is formed by using metal so as to have a porous structure.

3. The semiconductor substrate according to claim 1, wherein the plurality of electrodes is formed of a resin material having electrical conductivity.

4. A semiconductor device comprising: the semiconductor substrate according to claim 1.

5. A semiconductor device comprising: the semiconductor substrate according to claim 2.

6. A semiconductor device comprising: the semiconductor substrate according to claim 3.

7. A solid-state imaging device comprising: the semiconductor device according to claim 4.

8. A solid-state imaging device comprising: the semiconductor device according to claim 2.

9. A solid-state imaging device comprising: the semiconductor device according to claim 6.

10. A method of manufacturing a semiconductor substrate comprising:
forming a resin layer on a surface on one side of a substrate;
forming a sacrificial layer on the resin layer;
forming an opening portion which penetrates the sacrificial layer and the resin layer and in which the substrate is exposed at a bottom portion;
filling an electrode material in the opening portion; and
removing the sacrificial layer, thereby forming an electrode which protrudes in a thickness direction of the substrate further than the resin layer.

11. The method of manufacturing a semiconductor substrate according to claim 10, wherein, in the thickness direction, a thickness of the sacrificial layer is greater than or equal to 5% of the sum of a thickness of the resin layer and the thickness of the sacrificial layer.
